(19) United States
(12) Patent Application Publication
(10) Pub. No.: US 2008/0246103 A1
(43) Pub. Date: Oct. 9, 2008

(54) MR device with surfactant layer within the free layer

(75) Inventors: Hui-Chuan Wang, Pleasanton, CA (US); Tong Zhao, Fremont, CA (US); Min Li, Dublin, CA (US); Kunliang Zhang, Milpitas, CA (US)

Correspondence Address: STEPHEN B. ACKERMAN, 28 DAVIS AVENUE, POUGHKEEPSIE, NY, 12603, US

(73) Assignee: Headway Technologies, Inc.

(21) Appl. No.: 11/784,076

(22) Filed: Apr. 5, 2007

(51) Int. Cl. H01L 43/00

(52) U.S. Cl. 257/421

(57) ABSTRACT

The dR/R ratios of TMR and GMR devices, having a FeCo/NiFe type of free layer, have been significantly increased by inserting a suitable surfactant layer within (as opposed to above or below) the free layer. Our preferred surfactant material has been oxygen but similar-acting materials could be substituted. The concept can be applied to GMR CPP, CIP, and CCP sensor designs.

### FIELD OF THE INVENTION

The invention relates to the general field of MR (magneto-resistance) based memory cells with particular reference to a free layer that is made up of multiple layers, such as FeCo and NiFe.

### BACKGROUND OF THE INVENTION

TMR (tunneling magneto-resistance) and GMR (giant magneto-resistance) sensors having only FeCo (bcc) for the free layer can have a large dR/R ratio, however the magnetic properties, such as Hc, Hk and magnetostriction, of such a FeCo free layer will be well outside the usable range. In a typical TMR production process one usually deposits NiFe (fcc) as an additional free layer in order to achieve a magnetically softer free layer. However, a FeCo/NiFe free layer will have its TMR ratio dramatically reduced compared to a FeCo only free layer.

A typical MR memory cell of the prior art is illustrated in FIG. 1. Seen there are magnetic pinning layer 11 (normally an antiferromagnetic layer of a material such as IrMn or MnPt), magnetically pinned layer 12 (either a ferromagnetic layer or, more commonly, a synthetic antiferromagnetic trilayer), transition layer 13 (either copper for a GMR device or a thin insulating layer for a TMR device), CoFe layer 14, NiFe layer 15 (which, together with layer 14, makes up the free layer), and capping layer 16.

The present invention discloses how to attain a high dR/R ratio without pushing other magnetic properties outside their acceptable limits.

A routine search of the prior art was performed with the following references of interest being found:

In U.S. Pat. No. 7,116,530, Gill discloses a CoFe/NiFe free layer. U.S. Pat. No. 7,054,114 (Jander et al) teaches a free layer comprising FeCo/FeNiCo/FeCo or other variations. U.S. Pat. No. 7,045,841 (Hong et al—Headway) shows an oxygen surfactant layer on a CoFe or NiFe pinned layer.

U.S. Pat. Nos. 7,042,684 and 6,993,827 (Hong et al—Headway) disclose a CoFe/NiFe free layer formed on an oxygen surfactant layer. The surfactant layer is, however, outside the free layer rather than within it.

### SUMMARY OF THE INVENTION

It has been an object of at least one embodiment of the present invention to attain a high dR/R ratio in a TMR or GMR memory element without pushing other magnetic properties of said memory element outside their acceptable limits Another object of at least one embodiment of the present invention has been to provide a structure that meets the preceding object along with a process for forming said structure.

Still another object of at least one embodiment of the present invention has been that the invention apply to CIP, CPP, and CCP type memory devices.

A further object of at least one embodiment of the present invention has been that adoption of said process require that only minor changes be made to current processes for manufacturing said memory elements.

These objects have been achieved by inserting a suitable surfactant layer within (as opposed to above or below) the free layer. Our preferred surfactant material has been oxygen but similar-acting materials could be substituted. The concept can be applied to GMR CPP, CIP, and CCP sensor designs. A description of how to apply the oxygen surfactant layer is provided together with data comparing the dR/R performance of prior art devices to devices made according to the teachings of the present invention.

### BRIEF DESCRIPTION OF THE DRAWINGS

FIG. 1 shows a typical memory element structure of the prior art.

FIG. 2 shows a memory element, similar to that of FIG. 1, modified according to the teachings of the present invention.

FIG. 3 extends the example shown in FIG. 2 to free layers made up of more than two ferromagnetic layers.

### DESCRIPTION OF THE PREFERRED EMBODIMENTS

We have been able to overcome the problems outlined in the background section by inserting a suitable surfactant layer into the free layer. Oxygen is allowed to flow across the surface of a FeCo free layer to form a thin surfactant layer (SL) between the FeCo and the NiFe bilayer that constitutes the free layer, the intent being to reduce the impact of the lattice mismatch between the NiFe (fcc) and the FeCo (bcc) components of the free layer.

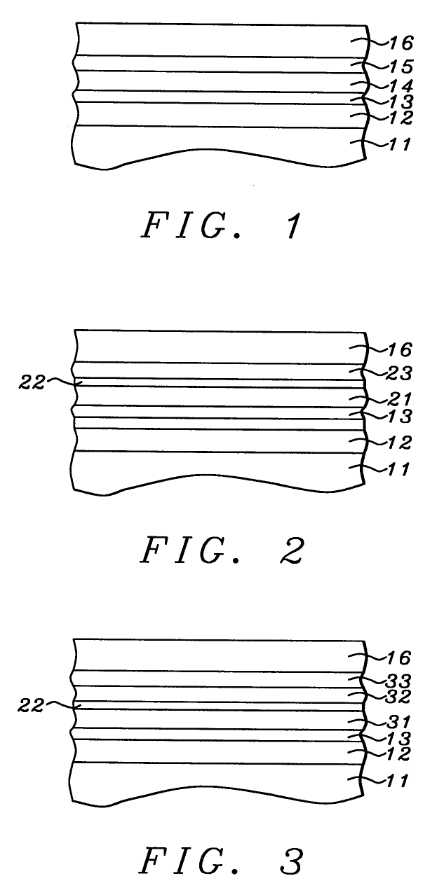

This is illustrated in FIG. 2 that can be seen to be similar to the prior art structure seen in FIG. 1 but with the key difference that, between layers 21 and 23 (which are equivalent to layers 14 and 15 in FIG. 1), surfactant layer 22 has been inserted. Layer 22 may be any of several known surfactant materials, such as oxygen, or oxygen mixed with argon, krypton, xenon, or neon, with oxygen being preferred.

Other, similar structures are possible, for example FeCo/SL/FeCo/NiFe or FeCo/SL/NiFe. With the SL inserted into the free layer, the crystal structure is improved (lattice strain reduced) and, additionally, the thin SL layer will also serve to reduce the diffusion of Ni from NiFe into FeCo. The net outcome, therefore, is that the TMR ratio of the sensor increases 20 to 30% relative to what would be obtained in a similar structure without the surfactant layer. FIG. 3 is a schematic illustration of the placement of the surfactant layer within the free layer. In this example it shows surfactant layer 22 located between layer 31 (FeCo) and layer 32 (FeCo), on which has been deposited layer 33 (NiFe).

An important question that needed to be answered at the outset was what effect, if any, insertion of the SL would have on the key magnetic properties of the free layer—Hc (coercivity), Hk (anisotropy field), and lambda (λ—magnetostriction coefficient). Experimental results are summarized in TABLE 1:

Sample structure: Seed/AFM/outer pinned/Ru/inner pinned/MgOx/Free/Cap

| | Samples | Free Layer | Hc | Hk | Lambda |
|---|---|---|---|---|---|
| | 1 | FeCo/SL/FeCo/NiFe | 4.56 | 15.29 | 1.56E−06 |
| | 2 | FeCo/SL/NiFe | 4.49 | 15.32 | 1.63E−06 |
| Ref. | 2 | FeCo/NiFe | 4.60 | 15.08 | 1.60E−06 |

TABLE 1 compares free layer properties with and without the SL.

From TABLE I it can be seen that the free layer properties do not change significantly after the SL has been inserted into it.

TABLE II shows experimental data for the RA (resistance.area) product (in ohms.μm²) and the TMR ratio across a 6″ TMR device wafer having a MgOx barrier and a SL inserted into the free layer, as outlined above.

Sample structure: Seed/AFM/outer pinned/Ru/inner pinned/MgOx/Free/Cap

TABLE II

| Samples | Free Layer | RA | dR/R |
|---|---|---|---|
| 1 | FeCo/SL/FeCo/NiFe | 2.3 | 55% |
| 2 | FeCo/SL/NiFe | 2.3 | 56% |
| Ref. | FeCo/NiFe | 2.3 | 44% |

From TABLE II we can see that high TMR ratio (dR/R), together with a low RA product, was obtained after applying a SL within the FeCo/NiFe free layer.

The same concept can also be applied to triple-layer free layers such as FeCo/FeNi/NiFe. TABLE III shows experimental data demonstrating the RA and TMR values across a 6″ device wafer for a TMR device with a MgOx barrier, the SL having been inserted within a FeCo/FeNi/NiFe triple layer free layer.

Sample: Seed/AFM/outer pinned/Ru/inner pinned/MgOx/Free/Cap

TABLE III

| Samples | Free Layer | RA | dR/R |
|---|---|---|---|
| 1 | FeCo/SL/FeNi/NiFe | 2.3 | 56% |
| 2 | FeCo/FeNi/SL/NiFe | 2.3 | 58% |
| Ref. | FeCo/NiFe | 2.3 | 44% |

From TABLE III it can be seen that an improved dR/R can also be achieved by inserting a thin surfactant layer (SL) within a FeCo/FeNi/NiFe triple layer free layer.

There are many different possible free layer structures into which a suitable surfactant layer may be inserted. These free layers, together with the various other layers needed to form a magneto-resistive magnetic memory element (pinned and pinning layers, and a transition layer such as a tunnel barrier layer in the case of a TMR device or a copper spacer layer in the case of a GMR device) are all formed through successive deposition of the layers listed in the several embodiments that are described below. It is to be understood that said embodiments are presented by way of illustrative examples and do not constitute an exhaustive list of all the possible combinations of ferromagnetic films that could be used to improve the performance of a free layer when the method of the present invention is applied to the formation of a magnetic memory cell.

Insertion of the surfactant layer is accomplished by depositing the surfactant on the appropriate layer within the free layer structure as soon as said appropriate layer has been laid down, followed by the deposition onto the surfactant layer of the next layer in the free layer deposition sequence.

We will now describe a process for depositing a surfactant layer of oxygen but it is to be understood that other similarly acting surfactant layers such as oxygen mixed with argon, krypton, xenon, or neon, could be used in place of oxygen without departing from the spirit and intent of the invention. To deposit the oxygen surfactant layer, we proceed as follows:

Within ______ minutes following free layer deposition, oxygen (optionally diluted by a noble gas) is admitted to the vacuum chamber to a pressure level of about 5×10⁻⁷ torr, for between about 5 and 60 seconds, thereby forming the aforementioned surfactant layer directly on the top surface of the freshly deposited free layer. This is immediately followed by deposition of any remaining layers that are part of the free layer. The R.A value of the completed device will be a function of the time for which the free layer was exposed to the oxygen (pure or diluted)—the longer this time the greater the resulting R.A value.

### 1^{st} Embodiment

The oxygen surfactant layer is inserted onto FeCoₓ (or, optionally, FeCoNi) and NiFe_{y} thereby creating the structure: FeCoₓ/SL/NiFe_{y}, where x=0˜100 at % and where y=0˜100 at %.

### 2^{nd} Embodiment

The oxygen surfactant layer is inserted between FeCoₓ (optionally with a third element added to make, for example, FeCoNi) thereby creating the structure: FeCoₓ/SL/FeCoₓ/NiFe_{y} where x=0˜100 at % and where y=0˜100 at %).

### 3^{rd} Embodiment

The free layer consists of a layer of FeCo on which is a layer of iron rich NiFe under a layer of nickel rich NiFe, the oxygen surfactant layer being inserted between the two NiFe layers, thereby creating the structure FeCoₓ/FeNi_{y}/SL/NiFe_{z}, where x, y, and z, individually, may have a value between 0 and 100%.

### 4^{th} Embodiment

The free layer consists of a layer of FeCo on which is a layer of CoFeQ under a layer of NiFe, the oxygen surfactant layer being inserted between the two NiFe layers, thereby creating the structure FeCoₓ/CoFeQ/SL/NiFe_{z}, where x and z, individually, may have a value between 0 and 100% and Q represents a third element such as B or Ni.

As noted earlier, all the above free layer structures may be utilized as part of either TMR or GMR devices. In the former case, devices having a dR/R ratio of at least 55% have been achieved while for GMR devices, dR/R ratios of at least 25% have been achieved. Also, for GMR devices, the processes and structures taught by the present invention are applicable to various types such as CIP (current in plane), CPP (current perpendicular to plane) and CCP (confined current path).

What is claimed is:

1. A method to increase magneto-resistance of a magnetically free layer, comprising:
providing a magnetic memory cell comprising a pinned layer on a pinning layer, a transition layer on said pinned layer, and said free layer on said transition layer, said free layer further comprising at least one layer containing cobalt and iron and at least one layer containing nickel and iron; and
inserting, only within said free layer a surfactant layer, thereby improving performance of said free layer.

2. The method of claim 1 wherein said surfactant layer is selected from the group consisting of oxygen, oxygen mixed with argon, oxygen mixed with krypton, oxygen mixed with xenon, and oxygen mixed with neon.

3. The method of claim 1 wherein said magnetic memory cell is a TMR device or a GMR device.

4. A process for forming, as part of a magnetic memory cell, a free layer, comprising:
depositing a magnetic pinning layer on a substrate;
depositing a magnetically pinned layer on said pinning layer;
depositing a transition layer on said pinned layer;
depositing, on said transition layer, a first ferromagnetic layer;
depositing, on said first ferromagnetic layer, a surfactant layer of oxygen; and
depositing, on said surfactant layer, a second ferromagnetic layer whereby said free layer, comprising said surfactant layer sandwiched between said first and second ferromagnetic layers, is formed.

5. The process of claim 4 wherein the step of depositing said surfactant layer of oxygen further comprises admitting oxygen to a pressure level of about 5×10⁻⁷ torr, for a time period whose magnitude is between about 5 and 60 seconds, whereby said magnetic memory cell acquires a R.A value that is proportional to the magnitude of said time period.

6. The process of claim 4 wherein the step of depositing a first ferromagnetic layer further comprises depositing a single layer containing iron and cobalt.

7. The process of claim 6 wherein the step of depositing a second ferromagnetic layer further comprises depositing a single layer containing iron and nickel.

8. The process of claim 6 wherein the step of depositing a second ferromagnetic layer further comprises depositing an iron rich layer containing iron and nickel and then depositing on said iron rich layer a nickel rich layer containing iron and nickel.

9. The process of claim 4 wherein the step of depositing a first ferromagnetic layer further comprises depositing a layer containing iron and cobalt followed by depositing, on said layer containing iron and cobalt, a layer containing iron and nickel.

10. The process of claim 9 wherein the step of depositing a second ferromagnetic layer further comprises depositing a single layer containing iron and nickel.

11. The process of claim 4 wherein the step of depositing a first ferromagnetic layer further comprises depositing a layer containing iron, cobalt and, optionally, nickel followed by depositing, on said layer containing iron, cobalt and, optionally, nickel a layer containing cobalt, iron, and a third element.

12. The process of claim 11 wherein said third element is selected from the group consisting of B and Ni.

13. The process of claim 11 wherein the step of depositing a second ferro-magnetic layer further comprises depositing, on said surfactant layer, a single layer containing nickel and iron.

14. The process of claim 4 wherein said transition layer is an insulated tunnel barrier layer whereby said magnetic memory cell is a TMR device having a dR/R ratio of at least 20%.

15. The process of claim 4 wherein said transition layer is a layer of copper whereby said magnetic memory cell is a GMR device having a dR/R ratio of at least 10%.

16. The process of claim 15 wherein said GMR device is of a type selected from the group consisting of CIP devices, CPP devices, and CCP devices.

17. A magnetic memory cell, including a free layer, comprising:
a magnetic pinning layer on a substrate;
a magnetically pinned layer on said pinning layer;
a transition layer on said pinned layer;
a first ferromagnetic layer on said transition layer;
a surfactant layer of oxygen on said first ferromagnetic layer; and
a second ferromagnetic layer on said surfactant layer, wherein said free layer, comprises said surfactant layer sandwiched between said first and second ferromagnetic layers.

18. The free layer described in claim 17 wherein said first ferromagnetic layer further comprises a single layer containing iron and cobalt.

19. The free layer described in claim 18 wherein said second ferromagnetic layer further comprises a single layer containing iron and nickel.

20. The free layer described in claim 17 wherein said second ferromagnetic layer further comprises a nickel rich layer containing iron and nickel on an iron rich layer containing iron and nickel.

21. The free layer described in claim 17 wherein said first ferromagnetic layer further comprises a layer containing iron and nickel on a layer containing iron and cobalt.

22. The free layer described in claim 21 wherein said second ferromagnetic layer further comprises a single layer containing iron and nickel.

23. The free layer described in claim 17 wherein said first ferromagnetic layer further comprises a layer containing cobalt, iron, and a third element, on a layer containing iron, cobalt and, optionally, nickel.

24. The free layer described in claim 23 wherein said third element is selected from the group consisting of B and Ni.

25. The free layer described in claim 23 wherein said second ferromagnetic layer further comprises a single layer containing nickel and iron.

26. The free layer described of claim 17 wherein said transition layer is an insulated tunnel barrier layer whereby said magnetic memory cell is a TMR device having a dR/R ratio of at least 20%.

27. The free layer described of claim 17 wherein said transition layer is a layer of copper whereby said magnetic memory cell is a GMR device having a dR/R ratio of at least 10%.

28. The free layer described of claim 27 wherein said GMR device is of a type selected from the group consisting of CIP devices, CPP devices, and CCP devices.
